(19) United States
(12) Patent Application Publication
(10) Pub. No.: US 2011/0022924 A1
(43) Pub. Date: Jan. 27, 2011

(54) Device and Method for Frame Erasure Concealment in a PCM Codec Interoperable with the ITU-T Recommendation G. 711

(76) Inventors: Vladimir Malenovsky, Sherbrooke (CA); Redwan Salami, St Laurent (CA)

Correspondence Address: FAY KAPLUN & MARCIN, LLP, 150 BROADWAY, SUITE 702, NEW YORK, NY, 10038, US

(21) Appl. No.: 12/664,024

(22) PCT Filed: Dec. 24, 2007
(86) PCT No.: PCT/CA2007/002357

§ 371 Date: Jun. 7, 2010

Related U.S. Application Data
(60) Provisional application No. 60/929,124, filed on Jun. 14, 2007.
(60) Provisional application No. 60/960,057, filed on Sep. 13, 2007.

(51) Int. Cl. H03M 13/05; G06F 11/10

(52) U.S. Cl. 714/752; 714/E11.032

(57) ABSTRACT

A device and method for resynchronization and recovery after frame erasure concealment of an encoded sound signal comprise decoding, in a current frame, a correctly received signal after the frame erasure. Frame erasure concealment is extended in the current frame using an erasure-concealed signal from a previous frame to produce an extended erasure-concealed signal. The extended erasure-concealed signal is correlated with the decoded signal in the current frame and the extended erasure-concealed signal is synchronized with the decoded signal in response to the correlation. A smooth transition is produced in the current frame from the synchronized extended erasure-concealed signal to the decoded signal.

### FIELD OF THE INVENTION

The present invention relates to a device and method for concealment and recovery from lost frames. More specifically, but not exclusively, the present invention relates to a device and method for concealment and recovery from lost frames in a multilayer embedded codec interoperable with ITU-T Recommendation G.711 and may use, for that purpose:
a packet loss concealment algorithm which is based on pitch and energy tracking, signal classification and energy attenuation; and
a signal resynchronization method that is applied in the decoder to smooth out sound signal transitions after a series of lost frames.

This method removes audible artefacts resulting from a changeover of unsynchronized concealed signal into a regularly decoded signal at the end of concealed segments.

### BACKGROUND OF THE INVENTION

The demand for efficient digital wideband speech/audio encoding techniques with a good subjective quality/bit rate trade-off is increasing for numerous applications such as audio/video teleconferencing, multimedia, wireless applications and IP telephony. Until recently the speech coding systems were able to process only signals in the telephony band, i.e. in the range 200-3400 Hz. Today, there is an increasing demand for wideband systems that are able to process signals in the range 50-7000 Hz. These systems offer significantly higher quality than the narrowband systems since they increase the intelligibility and naturalness of the sound. The bandwidth 50-7000 Hz was found sufficient to deliver a face-to-face quality of speech during conversation. For audio signals such as music, this range gives an acceptable audio quality but still lower than that of a CD which operates on the range 20-20000 Hz.

ITU-T Recommendation G.711 at 64 kbps and ITU-T Recommendation G.729 at 8 kbps are speech coding standards concerned with two codecs widely used in packet-switched telephony applications. Thus, in the transition from narrowband to wideband telephony there is an interest to develop wideband codecs backward interoperable to these two standards. To this effect, the ITU-T has approved in 2006 Recommendation G.729.1 which is an embedded multi-rate coder with a core interoperable with ITU-T Recommendation G.729 at 8 kbps. Similarly, a new activity has been launched in March 2007 for an embedded wideband codec based on a narrowband core interoperable with ITU-T Recommendation G.711 (both μ-law and A-law) at 64 kbps. This new G.711-based standard is known as the ITU-T Recommendation G.711 wideband extension (G.711 WBE).

In G.711 WBE, the input signal is sampled at 16 kHz and then split into two bands using a QMF (Quadrature Mirror Filter) analysis: a lower band from 0 to 4000 Hz and an upper band from 4000 to 7000 Hz. For example, if the bandwidth of the input signal is 50-8000 Hz the lower and upper bands can then be 50-4000 Hz and 4000-8000 Hz, respectively. In the G.711 WBE, the input wideband signal is encoded in three Layers. The first Layer (Layer 1; the core) encodes the lower band of the signal in a G.711-compatible format at 64 kbps. Then, the second Layer (Layer 2; narrowband enhancement layer) adds 2 bits per sample (16 kbit/s) in the lower band to enhance the signal quality in this band. Finally, the third Layer (Layer 3; wideband extension layer) encodes the higher band with another 2 bits per sample (16 kbit/s) to produce a wideband synthesis. The structure of the bitstream is embedded, i.e. there is always Layer 1 after which comes either Layer 2 or Layer 3 or both (Layer 2 and Layer 3). In this manner, a synthesized signal of gradually improved quality may be obtained when decoding more layers. For example, FIG. 1 is a schematic block diagram illustrating the structure of an example of the G.711 WBE encoder, FIG. 2 is a schematic block diagram illustrating the structure of an example of G.711 WBE decoder, and FIG. 3 is a schematic diagram illustrating the composition of an example of embedded structure of the bitstream with multiple layers in the G.711 WBE codec.

ITU-T Recommendation G.711, also known as a companded pulse code modulation (PCM), quantizes each input sample using 8 bits. The amplitude of the input sound signal is first compressed using a logarithmic law, uniformly quantized with 7 bits (plus 1 bit for the sign), and then expanded to bring it back to the linear domain. ITU-T Recommendation G.711 defines two compression laws, the μ-law and the A-law. Also, ITU-T Recommendation G.711 was designed specifically for narrowband input sound signals in the telephony bandwidth, i.e. in the range 200-3400 Hz. Therefore, when it is applied to signals in the range 50-4000 Hz, the quantization noise is annoying and audible especially at high frequencies (see FIG. 4). Thus, even if the upper band (4000-7000 Hz) of the embedded G.711 WBE is properly coded, the quality of the synthesized wideband signal could still be poor due to the limitations of legacy G.711 to encode the 0-4000 Hz band. This is the reason why Layer 2 was added in the G.711 WBE standard. Layer 2 brings an improvement to the overall quality of the narrowband synthesized sound signal as it decreases the level of the residual noise in Layer 1. On the other hand, it may result in an unnecessarily higher bit-rate and extra complexity. Also, it does not solve the problem of audible noise when decoding only Layer 1 or only Layer 1+Layer 3. The quality can be significantly improved by the use of noise shaping. The idea is to shape the G.711 residual noise according to some perceptual criteria and masking effects so that it is far less annoying for listeners. This technique is applied in the encoder and it does not affect interoperability with ITU-T Recommendation G.711. In other words, the part of the encoded bitstream corresponding to Layer 1 can be decoded by a legacy G.711 decoder (with increased quality due to proper noise shaping).

As the main applications of the G.711 WBE codec are in voice-over-packet networks, increasing the robustness of the codec in case of frame erasures becomes of significant importance. In voice-over-packet network applications, the speech signal is packetized where usually each packet corresponds to 5-20 ms of sound signal. In packet-switched communications, a packet dropping can occur at a router if the number of packets becomes very large, or the packet can reach the receiver after a long delay and it should be declared as lost if its delay is more than the length of a jitter buffer at the receiver end. In these systems, the codec is subjected to typically 3 to 5% frame erasure rates. Furthermore, the use of wideband speech encoding is an important asset to these systems in order to allow them to compete with traditional PSTN (Public Switched Telephone Network) that uses the legacy narrow band speech signals. Thus maintaining good quality in case of packet loss rates is very important.

ITU-T Recommendation G.711 is usually less sensitive to packet loss compared to prediction based low bit rate coders. However, at high packet loss rate proper packet loss concealment need to be deployed, especially due to the high quality expected from the wideband service.

### SUMMARY OF THE INVENTION

To achieve this goal, there is provided, according to the present invention, a method for resynchronization and recovery after frame erasure concealment of an encoded sound signal, the method comprising: in a current frame, decoding a correctly received signal after the frame erasure; extending frame erasure concealment in the current frame, using an erasure-concealed signal from a previous frame to produce an extended erasure-concealed signal; correlating the extended erasure-concealed signal with the decoded signal in the current frame and synchronizing the extended erasure-concealed signal with the decoded signal in response to the correlation; and producing in the current frame a smooth transition from the synchronized extended erasure-concealed signal to the decoded signal.

The present invention is also concerned with a device for resynchronization and recovery after frame erasure concealment of an encoded sound signal, the device comprising: a decoder for decoding, in a current frame, a correctly received signal after the frame erasure; a concealed signal extender for producing an extended erasure-concealed signal in the current frame using an erasure-concealed signal from a previous frame; a correlator of the extended erasure-concealed signal with the decoded signal in the current frame and a synchronizer of the extended erasure-concealed signal with the decoded signal in response to the correlation; and a recovery unit supplied with the synchronized extended erasure-concealed signal with the decoded signal, the recovery unit being so configured as to produce in the current frame a smooth transition from the synchronized extended erasure-concealed signal to the decoded signal.

The device and method ensure that the transition between the concealed signal and the decoded signal is smooth and continuous. These device and method therefore remove audible artefacts resulting from a changeover of unsynchronized concealed signal into a regularly decoded signal at the end of concealed segments.

The foregoing and other objects, advantages and features of the present invention will become more apparent upon reading of the following non restrictive description of an illustrative embodiment thereof, given by way of example only with reference to the accompanying drawings.

### BRIEF DESCRIPTION OF THE DRAWINGS

In the appended drawings:

FIG. 1 is a schematic block diagram illustrating the structure of the G.711 WBE encoder;

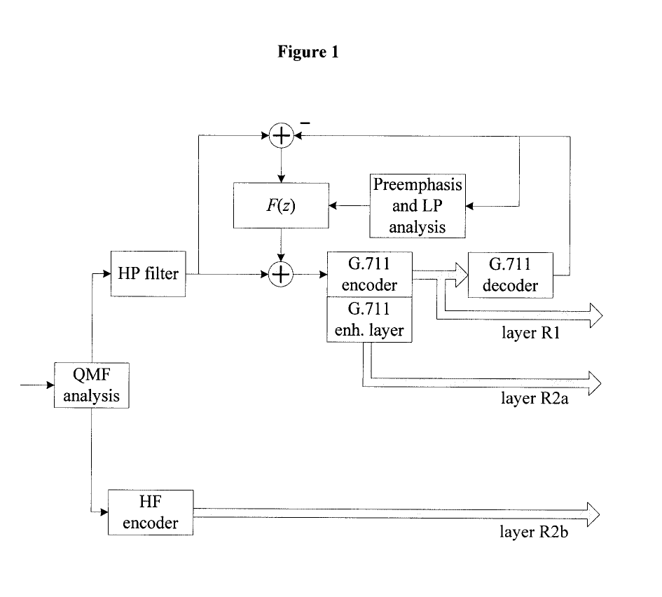

FIG. 2 is a schematic block diagram illustrating the structure of the G.711 WBE decoder;

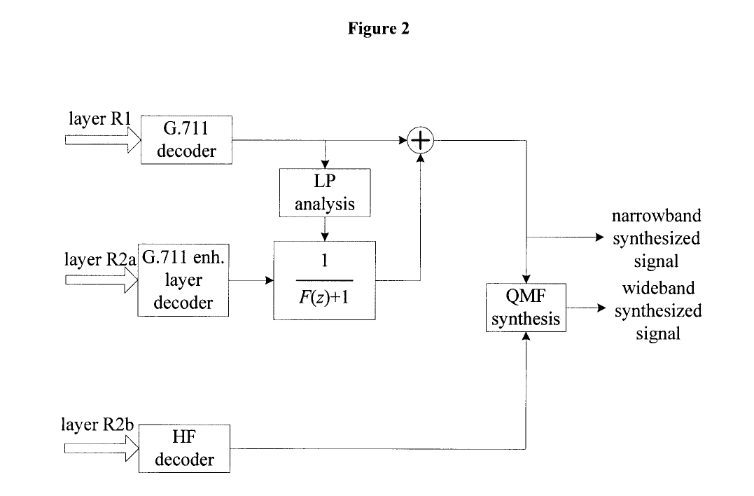

FIG. 3 is a schematic diagram illustrating the composition of the embedded bitstream with multiple layers in the G.711 WBE codec;

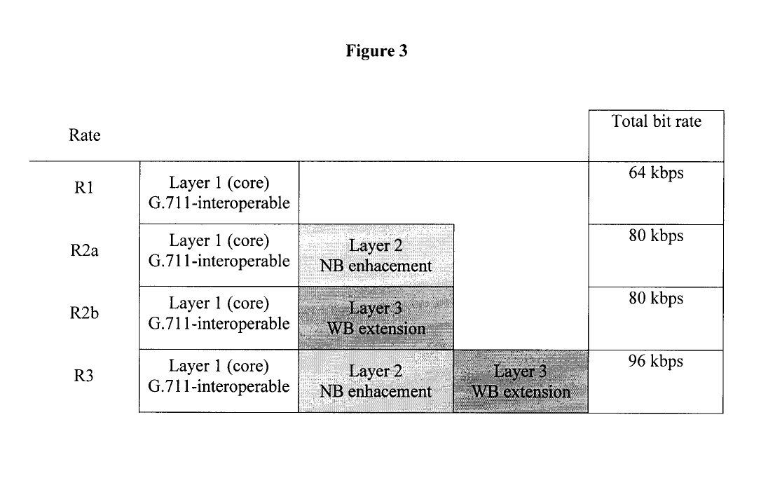

FIG. 4 is a block diagram of the different elements and operation involved in the signal resynchronization;

FIG. 5 is a graph illustrating the Frame Erasure Concealment processing phases;

FIG. 6 is a graph illustrating the Overlap-Add operation (OLA) as part of the recovery phase after a series of frame erasures; and

FIG. 7 are graphs illustrating signal resynchronization.

### DETAILED DESCRIPTION OF THE ILLUSTRATIVE EMBODIMENT

The non-restrictive illustrative embodiment of the present invention is concerned with concealment of erased frames in a multilayer embedded G.711-interoperable codec. The codec is equipped with a frame erasure concealment (FEC) mechanism for packets lost during transmission. The FEC is implemented in the decoder, it works on a frame-by-frame basis and makes use of a one frame lookahead.

The past narrowband signal (Layer 1, or Layer 1 & 2) is used for conducting an open-loop (OL) pitch analysis. This is performed by a pitch-tracking algorithm to ensure a smoothness of the pitch contour by exploiting adjacent values. Further, two concurrent pitch evolution contours are compared and the track that yields smoother contour is selected.

To improve the efficiency of FEC, a signal classification algorithm is used to classify the frame as unvoiced, voiced, or transition. Subclasses are used to further refine the classification. In one illustrative embodiment, at the end of each frame, energy and pitch evolution are estimated for being used at the beginning of Frame Erasure Concealment (FEC). An Overlap-Add (OLA) mechanism is used at the beginning and at the end of the FEC. For stable voiced signals, the FEC algorithm comprises repeating the last known pitch period of the sound signal, respecting the pitch and energy evolution estimated before frame erasure. For unvoiced frames, the past synthesized signal is used to perform an LP analysis and to calculate an LP filter. A random generator is used to create a concealed frame which is synthesized using the LP filter. Energy is adjusted in order to smooth transitions. For long erasures, gradual energy attenuation is applied. The slope of the attenuation depends on signal class and pitch period. For stable signals, the attenuation is mild whereas it is rapid for transitions.

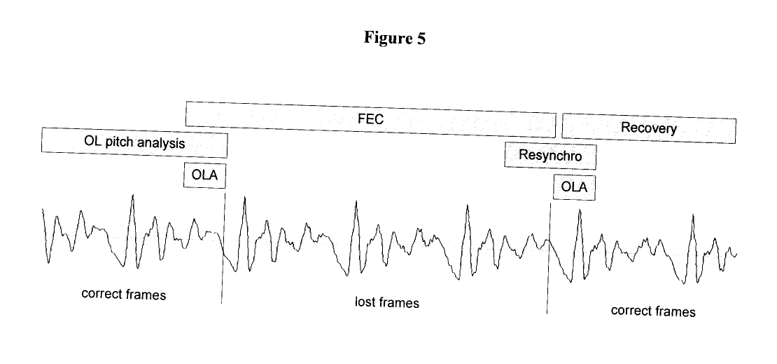

In the first correctly received frame after FEC, the sound signal is resynchronized by performing a correlation analysis between an extended concealed signal and the correctly received signal. The resynchronization is carried out only for voiced signals. After frame erasure concealment is completed a recovery phase is initiated which comprises applying an OLA mechanism and energy adjustment. The FEC phases are shown in FIG. 5.

The FEC algorithm may be designed to maintain a high quality synthesized sound signal in case of packet losses. In the non-restrictive illustrative embodiment, a “packet” refers to information derived from the bitstream which is used to create one frame of synthesized sound signal.

The FEC algorithm capitalizes on a one-frame lookahead in the decoder. Using this lookahead means that, to produce a synthesized frame of speech, the decoder has to “look at” (or use) information of the next frame. Thus, when a lost frame is detected, the concealment mechanism effectively starts from the first frame after the erasure. Consequently, upon receiving a first correct packet after a series of erasures, the FEC may use this first correctly received frame to retrieve some information for the last concealed frame. In this way, transitions are smoothed at the beginning and at the end of the concealed signal.

Open-Loop Pitch Analysis

With every new synthesized frame in the decoder, pitch analysis is performed to estimate the open-loop (OL) pitch which is used in the FEC. The OL pitch analysis is carried out on the narrowband signal. As a non-limitative example, this OL pitch analysis uses a window of 300 samples. The OL pitch algorithm is based on a correlation analysis which is done in four (4) intervals of pitch lags, namely [13,20], [21,39], [40,76] and [77, 144] (at a 8000 Hz sampling rate). The summation length in each interval is given by:

L_{sec}=50 for section [13,20]

L_{sec}=50 for section [21,39]

L_{sec}=78 for section [40,76]

L_{sec}=144 for section [77,144]. (1)

An autocorrelation function is computed for each pitch lag value using the following relation:

$$C ( d ) = {\sum }_{n = 0}^{{L}_{sec}} s ( N - {L}_{sec} + n ) s ( N - {L}_{sec} + n - d ) \qquad ( 2 )$$

where s(n) is the currently synthesized frame of speech including a past synthesis buffer, d is the pitch lag (delay) and N is the frame length. For example, N=40 that is 5 ms at a sampling frequency of 8000 Hz.

The autocorrelation function is then weighted by a triangular window in the neighbourhood of the OL pitch lag determined in the previous frame. This strengthens the importance of the past pitch value and retain pitch coherence. The details of the autocorrelation reinforcement with past pitch value may be found in Reference [2] which is herein incorporated by reference. The weighted autocorrelation function will be denoted as C^{w} (.).

After weighting the autocorrelation function with the triangular window, the maxima in each of the four (4) intervals are determined along with their corresponding pitch lags. The maxima are normalized using the following relation:

$${C}_{norm}^{w} ( {d}_{max} ) = \frac{{C}^{w} ( {d}_{max} )}{\sqrt{{\sum }_{n = 0}^{{L}_{sec}} {s}^{2} ( n ) {\sum }_{n = 0}^{{L}_{sec}} {s}^{2} ( n - {d}_{max} )}} \qquad ( 3 )$$

From now on, the maxima of the normalized weighted autocorrelation function in each of the four (4) intervals will be denoted as X₀, X₁, X₂, X₃ and their corresponding pitch lags as d₀, d₁, d₂, d₃. All remaining processing is performed using only these selected values, which reduces the overall complexity.

In order to avoid selecting pitch multiples, the correlation maximum in a lower-pitch lag interval is further emphasized if one of its multiples is in the neighbourhood of the pitch lag corresponding to the correlation maximum in a higher-pitch lag interval. This is called the autocorrelation reinforcement with pitch lag multiples and more details on this topic are given in Reference [2]. The modified set of correlation maxima will be therefore Xc₀, Xc₁, Xc₂, Xc₃. It should be noted that Xc₃=X₃ since the highest-pitch lag interval is not emphasized. Finally, the maxima Xcᵢ in each of the four (4) intervals are compared and the pitch lag that corresponds to the highest maximum becomes the new OL pitch value. In the following disclosure, the highest maximum between Xc₀, Xc₁, Xc₂, and Xc₃ will be denoted as Cₘₐₓ.

Signal Classification

To choose an appropriate FEC strategy, signal classification is performed on the past synthesized signal in the decoder. The aim is to categorize a signal frame into one of the following 5 classes:
class 0: UNVOICED
class 1: UNVOICED TRANSITION
class 2: VOICED TRANSITION
class 3: VOICED
class 4: ONSET

The signal classification algorithm is based on a merit function which is calculated as a weighted sum of the following parameters: pitch coherence, zero-crossing rate, maximum normalized correlation, spectral tilt and energy difference.

The maximum normalized correlation Cₘₐₓ has already been described in the previous section.

The zero-crossing rate zc will not be described in the present specification since this concept is believed to be well-known to those of ordinary skill in the art.

The spectral tilt eₜ is given by the following relation:

$${e}_{t} = \frac{{\sum }_{n = - N}^{N - 1} s ( n ) s ( n - 1 )}{{\sum }_{n = - N}^{N - 1} s ( n ) s ( n )} \qquad ( 4 )$$

where the summation begins at the last synthesized frame and ends at the end of the current synthesized frame. The spectral tilt parameter contains information about the frequency distribution of the speech signal.

The pitch coherence pc is given by the following relation:

pc=|T_{OL}⁽⁰⁾+T_{OL}⁽⁻¹⁾−T_{OL}⁽⁻²⁾−T_{OL}⁽⁻³⁾| (5)

where T_{OL}⁽⁰⁾ is the OL pitch period in the current frame and T_{OL}⁽⁻ⁱ⁾, i=1, 2, 3 are the OL pitch periods in past frames.

The pitch-synchronous relative energy at the end of a frame is given by the relation:

ΔE_{T}=E_{T}−Ē_{T} (6)

where

$${E}_{T} = 10 {log}_{10} ( \frac{1}{{T}^{′}} {\sum }_{n = 0}^{{T}^{′} - 1} {s}^{2} ( N - {T}^{′} + n ) ) \qquad ( 7 )$$

is the pitch-synchronous energy calculated at the end of the synthesized signal, Ē_{T} is the long-term value of this calculated pitch-synchronous energy and T′ is a rounded average of the current pitch and the last OL pitch. If T′ is smaller than N, T′ is multiplied by 2. The long-term energy is updated only when a current frame is classified as VOICED using the relation:

Ē_{T}=0.99Ē_{T}+0.01E_{T} (8)

Each classification parameter is scaled so that its typical value for unvoiced signal would be 0 and its typical value for the voiced signal would be 1. A linear function is used between them. The scaled version p^{s} of a certain parameter p is obtained using the relation:

p^{s}=k·p+c (9)

where the constants k and c vary according to Table 1. The scaled version of the pitch coherence parameter is limited by <0;1>.

The merit function has been defined as:

$${f}_{m} = \frac{1}{6} ( 2 {C}_{max}^{s} + {pc}^{s} + {e}_{t}^{s} + {zc}^{s} + Δ {E}_{t}^{s} ) \qquad ( 10 )$$

where the superscript s indicates the scaled version of the parameters.

TABLE 1
Coefficients of the scaling function
for signal classification parameters

| Parameter | Meaning | k | c |
|---|---|---|---|
| Cₘₐₓ | Max. normalized correlation | 0.8547 | 0.56 |
| eₜ | Spectral tilt | 0.8333 | 0.2917 |
| pc | Pitch coherence | −0.0357 | 1.6071 |
| ΔEₜ | Pitch-synchr. relative energy | 0.04 | 0.56 |
| zc | Zero-crossing counter | −0.0833 | 1.6667 |

The classification is performed using the merit function fₘ and the following rules:

```
If (last_clas was ONSET, VOICED or VOICED TRANSITION)
    If (fₘ < 0.39) clas = UNVOICED
    If (0.39 ≦ fₘ < 0.63) clas = VOICED TRANSITION
    If (0.63 ≦ fₘ) clas = VOICED
Else
    If (fₘ ≦ 0.45) clas = UNVOICED
    If (0.45 < fₘ ≦ 0.56) clas = UNVOICED TRANSITION
    If (0.56 < fₘ) clas = ONSET
End
```

The clas parameter is the classification of the current frame and last_clas is the classification of the last frame.

Pre-Concealment

When the current frame cannot be synthesized because of a lost packet, the FEC algorithm generates a concealed signal instead and ensures a smooth transition between the last correctly synthesized frame and the beginning of the concealed signal. This is achieved by extrapolating the concealed signal ahead of the beginning and conducting an Overlap-Add (OLA) operation between the overlapping parts. However, the OLA is applied only when the last frame is voiced-like, i.e. when (clas>UNVOICED TRANSITION).

First, one frame of concealed signal is generated based on the last correct OL pitch. The concealment respects pitch and energy evolution at the very beginning and applies some energy attenuation towards the end of the frame. In the following description, s(n) will denote the last correctly synthesized frame. The concealed signal is given by the following relation:

s_{X}(n)=s(n+N−T_{OL}), n=0,1, . . . , N−1. (11)

The length of the segment over which the OLA operation is performed is the quarter of the OL pitch period, i.e. L_{OLA}=T_{OL}/4. Therefore, additional L_{OLA} samples of the concealed signal are generated ahead of s_{X}(n) for the OLA operation. This is reflected by the following relation:

s_{X}(n)=s(n+N−T_{OL}), n=−L_{OLA}, . . . , −1,0,1, . . . , N−1. (12)

For the OLA operation, the following linear function is defined:

$${f}_{OLA} ( i ) = 1 - \frac{i}{{L}_{OLA}} , i = 0 , 1 , … , {L}_{OLA} \qquad ( 13 )$$

The terminating segment of the last correctly synthesized frame is then modified as follows:

$$s ( n + N - {L}_{OLA} ) = s ( n + N - {L}_{OLA} ) {f}_{OLA} ( n ) ++ {s}_{x} ( n - {L}_{OLA} ) [ 1 - {f}_{OLA} ( n ) ] , \\ n = 0 , 1 , … , {L}_{OLA} - 1 \qquad ( 14 )$$

and the leading segment of the extrapolated concealed frame as:

sf_{OLA}(n−L_{OLA})=sf(n−L_{OLA})(1−f_{OLA}(n)), n=0,1, . . . , L_{OLA} (15)

Pitch Evolution

For voiced-like signals, i.e. when clas>UNVOICED TRANSITION, the last pitch period of the synthesized signal is repeated and modified to respect pitch evolution estimated at the end of the last correctly synthesized frame. The estimation of pitch evolution is part of the OL pitch tracking algorithm. It starts by calculating the pitch coherency flag, which is used to verify if pitch evolves in a meaningful manner. The pitch coherency flag coh_flag(i) is set if the following two conditions are satisfied:

$$\frac{max ( {T}_{OL}^{( i )} , {T}_{OL}^{( i - 1 )} )}{min ( {T}_{OL}^{( i )} , {T}_{OL}^{( i - 1 )} )} < 1.4 \\ max ( {T}_{OL}^{( i )} , {T}_{OL}^{( i - 1 )} ) - min ( {T}_{OL}^{( i )} , {T}_{OL}^{( i - 1 )} ) < 18. \qquad ( 16 )$$

The above test is carried out for i=0, −1, −2, i.e. for the last three OL pitch periods.

The pitch evolution factor delta_pit is calculated as the average pitch difference in the last pitch-coherent segment. The pitch-coherent segment is delimited by the positive coherency flag starting at i=0. Thus, if coh_flag(0) and coh_flag(−1) are both equal to one and coh_flag(−2) is equal to zero, the pitch-coherent segment is for i=0 and i=−1. It can then be written:

$$delta\_pit = \frac{1}{\vert {i}_{pc} \vert} {\sum }_{{i}_{pc}}^{i = 0} {T}_{OL}^{( i )} - {T}_{OL}^{( i - 1 )} \qquad ( 17 )$$

where i_{pc} is the last index in the pitch-coherent segment. The pitch evolution factor is limited in the interval <−3;3>.

When the pitch evolution factor is positive, the concealed frame is stretched by inserting some samples therein. If the pitch evolution factor is negative, the concealed frame is shortened by removing some samples therefrom. The sample insertion/removal algorithm assumes that the concealed signal is longer than one frame so that the boundary effects resulting from the modification are eliminated. This is ensured by means of concealed signal extrapolation.

With every new concealed frame, the pitch evolution factor is first decreased by one if it was positive or increased by one if it was negative. This ensures that after 3 consecutive frame erasures the pitch evolution is finished. The absolute value of the pitch evolution factor defines also the number of samples to be inserted or removed, that is:

Nₚ=|delta_pit| (18)

The concealed frame is divided into Nₚ+1 regions and in every region a point with the lowest energy is searched. A low-energy point is defined as:

n_{LE}=arg min(sf²(n)+sf²(n+1)) (19)

The low-energy points in all regions are numbered as n_{LE}⁽ⁱ⁾, where i=0, 1, . . . , Nₚ. They point to locations, where the samples are to be inserted or removed.

A sample is inserted or removed at the position pointed to by n_{LE}⁽ⁱ⁾ and the remaining part of the concealed frame is shifted accordingly. If a sample is inserted, its value is calculated as the average value of its neighbours. If samples are removed, new samples are taken from the extrapolated part beyond the end of the concealed frame to fill-in the gap. This ensures that the concealed signal will always have the length of N.

Concealment of Unvoiced Frames

As mentioned in the previous section, for voiced-like signals, i.e. when clas>UNVOICED TRANSITION, the last pitch period of the synthesized signal is repeated. For unvoiced-like signals, the pitch evolution is not important is not respected.

For unvoiced-like signals, the FEC is performed in a residual domain. First, a linear prediction (LP) analysis is done on the last 120 samples of the past synthesized signal to retrieve a set of LP filter coefficients aᵢ, i=0, 1, . . . , 8. The LP analysis is made using the autocorrelation principle and Levinson-Durbin algorithm. The details of the LP analysis are not given here since this technique is believed to be well-known to those of ordinary skill in the art.

The samples of the concealed unvoiced frame are generated by a pseudo-random generator, where each new sample is given by:

x(n)=31821·x(n−1)+13849, n=1,2, . . . , N (20)

The random generator is initialized with g(0)=21845 (other values can be used). Then, the random signal is synthesized using the LP coefficients found before, i.e.:

$${S}_{SYN} ( n ) = x ( n ) - {\sum }_{i = 1}^{8} {a}_{i} {s}_{SYN} ( n - i ) n = 0 , 1 , … , N - 1 \qquad ( 21 )$$

The energy of the synthesized signal is adjusted to the energy of the previous frame, i.e.:

sf(n)=gₐs_{SYN}(n), n=0,1, . . . , N−1 (22)

where the gain gₐ is defined as the square-root of the ratio between the past frame energy and the energy of the random synthesized frame. That is

$${g}_{a} = \sqrt{\frac{{\sum }_{i = 0}^{N - 1} {s}^{2} ( n - N )}{{\sum }_{i = 0}^{N - 1} {s}_{SYN}^{2} ( n )}} \qquad ( 23 )$$

To summarize, Equation (11) specifies the concealed frame for a voiced-like signals which is further modified with respect to pitch evolution and Equation (22) specifies a concealed frame for an unvoiced-like signal.

Energy Attenuation

For both type of signals, i.e. voiced and unvoiced, the energy of the concealed signal is gradually attenuated as the number of erasures progresses. The attenuation algorithm is equipped with a detector of voiced offsets during which it tries to respect the decreasing energy trend. It is also capable of detecting some badly developed onsets and applies a different attenuation strategy. The parameters of the attenuation algorithm have been hand-tuned to provide a high subjective quality of the concealed signal.

A series of attenuation factors is calculated when the first erased frame is detected and used throughout the whole concealment. Each attenuation factor specifies a value of the gain function at the end of the respective frame to be applied on the concealed signal. The series of attenuation factors is given by the following relation:

gₐₜₜ=[1,g(0),g(1), . . . , g(N_{ATT})=0] (24)

where N_{ATT}⁼20 is the length of the series. The series starts with 1 and ends with zero. This indicates that the energy at the beginning of the concealed frame is not attenuated and the energy at the end of the concealed frame is attenuated to zero. Table 2 shows the attenuating factors for various signal classes.

TABLE 2
Attenuation factors used during the frame erasure concealment

| index | UNV | UNV_TRAN | VOI_TRAN | VOI | ONS |
|---|---|---|---|---|---|
| 0 | 1.0 | 0.8 | 1.0 | 1.0 | 1.0 |
| 1 | 1.0 | 0.6 | 1.0 | 1.0 | 1.0 |
| 2 | 0.7 | 0.4 | 0.7 | 1.0 | 0.7 |
| 3 | 0.4 | 0.2 | 0.4 | 1.0 | 0.4 |
| 4 | 0.1 | 0 | 0.1 | 1.0 | 0.1 |
| 5 | 0 | | 0 | 1.0 | 0 |
| 6 | | | | 1.0 | |
| 7 | | | | 1.0 | |
| 8 | | | | 0.8 | |
| 9 | | | | 0.6 | |
| 10 | | | | 0.4 | |
| 11 | | | | 0.2 | |
| 12-20 | | | | 0 | |

For voiced-like signals (clas>VOICED TRANSITION) pitch-synchronous energy is calculated at the end of each synthesized frame by means of the following relation:

$${E}_{FEC} = log ( \frac{1}{{T}_{OL}^{( 0 )}} {\sum }_{i = 0}^{{T}_{OL}^{( 0 )}} {s}^{2} ( n + N - {T}_{OL}^{( 0 )} ) ) \qquad ( 25 )$$

The energy trend is estimated using the Least-Squares (LS) approach. The following first-order linear function is used to approximate the evolution of the last five (5) energy values:

f_{E}(i)=k·t(i)+q (26)

where t=[4N, 3N, 2N, N, 0] is a vector of time indices, i=0, 1, . . . , 4 and f_{E}(i) are the approximated energy values. The coefficients k and q are given by

$$\begin{matrix}k = \frac{5 {\sum }_{i = 0}^{4} t ( i ) {E}_{FEC}^{( - i )} - {\sum }_{i = 0}^{4} t ( i ) {\sum }_{i = 0}^{4} {E}_{FEC}^{( - i )}}{5 {\sum }_{i = 0}^{4} {t}^{2} ( i ) - {( {\sum }_{i = 0}^{4} t ( i ) )}^{2}} \\ q = \frac{{\sum }_{i = 0}^{4} {t}^{2} ( i ) {\sum }_{i = 0}^{4} {E}_{FEC}^{( - i )} - {\sum }_{i = 0}^{4} t ( i ) {\sum }_{i = 0}^{4} t ( i ) {E}_{FEC}^{( - i )}}{5 {\sum }_{i = 0}^{4} {t}^{2} ( i ) - {( {\sum }_{i = 0}^{4} t ( i ) )}^{2}} ,\end{matrix} \qquad ( 27 )$$

where the negative indexes to E_{FEC}(.) refer to the past energy values. A mean-squared error is calculated using the relation:

$$err = \frac{1}{3} {\sum }_{i = 0}^{4} {( {f}_{E} ( i ) - {E}_{FEC}^{( - i )} )}^{2} \qquad ( 28 )$$

and an energy trend is given by

E_{trend}=k·N (29)

These two parameters are used by the attenuation algorithm to detect voiced offsets. The algorithm first verifies if the last five (5) correctly synthesized frames were classified as voiced-like, i.e. if they satisfy the condition clas>UNVOICED TRANSITION. Furthermore, for the attenuation algorithm, voiced offsets must meet the following condition:

(E_{trend}<−0.1) AND (err<0.6) (30)

The series of attenuation factors for voiced offsets is defined as:

gₐₜₜ=[1,10^{1/2E}^{_{trend}},10^{E}^{_{trend}},10^{3/2E}^{_{trend}}, . . . , 0]. (31)

This ensures that the energy trend estimated before the erasure of voiced offset is maintained also during the concealment.

The attenuation algorithm applies a different attenuation strategy for false or badly developed onsets. To detect such frames, the following condition must be satisfied

[(clas⁽⁰⁾==ONSET)∥(clas⁽⁻¹⁾==ONSET)∥(clas⁽⁻²⁾)] AND [((E_{FEC}⁽⁰⁾<E_{FEC}⁽⁻¹⁾) AND (E_{FEC}⁽⁻¹⁾<E_{FEC}⁽⁻²⁾) AND (E_{FEC}⁽⁰⁾/E_{FEC}⁽⁻²⁾<0.9)) OR (Cₘₐₓ<0.6)]

where the indexes denote frame numbers, starting with 0 for the last correctly synthesized frame. The series of attenuation factors for onsets detected in this way is given by:

gₐₜₜ=[1,w(0),w(1), . . . , w(N_{ATT})=0] (32)

where w(.) is a linear function initialized by w(0)=1 and updated at the end of each frame as:

w(i)=w(i−1)−[−0.006T_{OL}⁽⁰⁾+0.82], i=1,2, . . . , N_{ATT} (33)

Thus, w(.) depends on the OL pitch period. It decreases more rapidly for short pitch periods and less rapidly for long periods.

Finally, the samples of every concealed frame are multiplied by a linear function which is an interpolation between two consecutive attenuation factors, i.e.:

sf_{ATT}(n)=sf(n)f_{ATT}(n), n=0,1, . . . , N−1 (34)

where f_{ATT}(.) is updated at the end of each frame by:

$${f}_{ATT} ( n ) = {g}_{ATT} ( i - 1 ) - \frac{{g}_{ATT} ( i ) - {g}_{ATT} ( i - 1 )}{N} n , \\ n = 0 , 1 , … , N - 1. \qquad ( 35 )$$

The updating in Equation (35) starts with i=1 (with g_{ATT}(0)=1) and i is incremented by one at the end of each frame. Equation (35) ensures that the gain will decrease gradually throughout the frame and will continue smoothly from frame to frame until zero is reached or the erasures stop.

The FEC concept comprising the repetition of the last pitch period (in case of voiced signals) or the resynthesis of a random signal (in case of unvoiced signals), followed by the modification due to pitch evolution and/or energy attenuation is repeated during the whole duration of frame erasures.

Signal Resynchronization

During concealment of voiced frames, as in Equation (11), the past signal is repeated using an estimated pitch lag. When the first good frame after a series of erasures is received, pitch discontinuity may appear which results in annoying artefact. The non-restrictive illustrative embodiment comprises a method for signal resynchronization to avoid this problem.

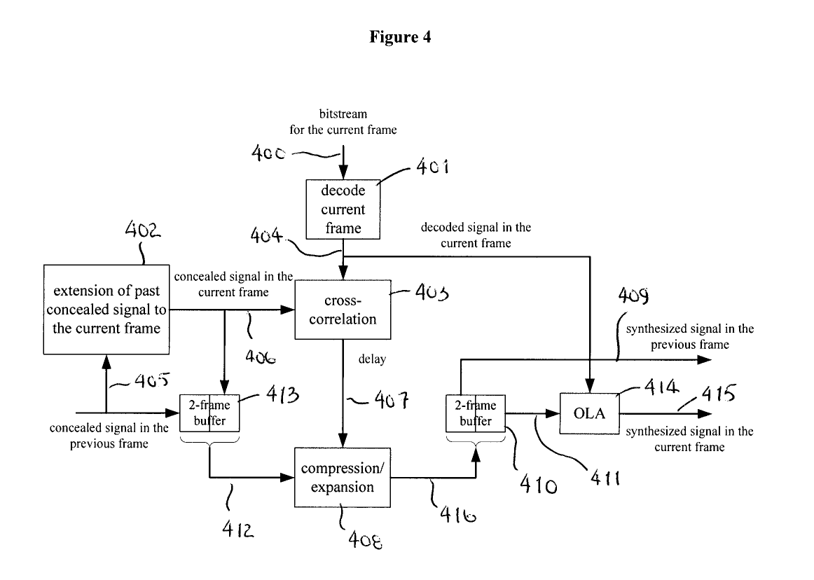

When the first good frame after a series of erasures is received, signal resynchronization is performed for voiced signals. The resynchronization is applied in the last concealed frame and the first correctly decoded frame to smooth out signal transitions and avoid the origin of artefacts. The principle of the disclosed signal resynchronization is shown in FIG. 4.

In decoder 401, the bitstream 400 of the first frame correctly received after frame erasure is decoded and synthesized to produce a decoded signal 404.

In concealed signal extender 402, a concealed signal 406 is generated in the current frame by the concealment algorithm which is a logical extension of the concealed signal 405 in the previous frame. More specifically, the concealment in the previous lost frame is continued in the current frame.

In cross-correlator 403, a cross-correlation analysis is performed between the two signals 404 and 406 in the current frame: the decoded signal 404 of the correctly received frame from the decoder 401 and the concealed signal 406 extended to the current frame by the extension unit 402. A delay 407 is extracted based on the cross-correlation analysis of cross-correlator 403.

The concealed signal 412 corresponding to the concatenation of the previous and current frames is supplied by a 2-frame buffer 412 receiving as inputs both the concealed signal 405 of the previous frame and the extended concealed signal 406 of the current frame. Based on the determined delay 407, a synchroniser 408 comprises a resampler for resampling the concealed signal 412 (corresponding to the concatenation of the previous and the current frame). For example, the resampler comprises a compressor or expander to compress or expand the concatenated concealed signal 412 depending on whether the delay 407 is positive or negative. The resulting resampled signal 416 is supplied to a 2-frame buffer 410. The idea is to align the phase of the concatenated concealed signal 412 with that of the decoded signal 404 from the correctly received frame.

After resampling the concealed signal (compression or expansion) in synchronizer 408, the part 409 of the resampled concealed signal corresponding to the previous frame is extracted and output through the 2-frame buffer 410. The part 411 of the resampled concealed signal corresponding to the current frame is extracted and output through the 2-frame buffer 410 and, then, is cross-faded with the decoded signal 404 of the correctly received frame using an OLA algorithm in recovery unit 414 to produce a synthesized signal 415 in the current frame. The OLA algorithm is described in detail in the following description.

In the first decoded frame after a series of packet losses, the concealment algorithm (extender 402) generates one more concealed signal 406 (in the same way as if the decoded frame was lost). A cross-correlation analysis (cross-correlator 403) is then performed between the concealed and the decoded signals in the range <−5;5>. Let the decoded signal be denoted as s(n) and the concealed signal as sₓ(n), where n=−N, . . . , 0, 1, . . . , N−1, where N is the frame size and is equal to 40 in this non-restrictive illustrative embodiment. It should be noted that the negative indices denote samples of the past concealed signal, i.e. prior to the decoded, correctly received frame. The correlation function is defined as:

$${X}_{RSX} ( i ) = {\sum }_{n = 0}^{N - {L}_{RSX} - 1} {s}_{x} ( i + n ) s ( n ) , i = {L}_{RSX} , … , {L}_{RSX} \qquad ( 36 )$$

where L_{RSX}=5 is the resynchronization interval. The maximum of the correlation function is found and the delay corresponding to this maximum is retrieved as follows:

$$\begin{matrix}{X}_{RSX}^{m} = {max}_{i = - {L}_{RSX} : {L}_{RSX}} ( {X}_{RSX} ( i ) ) \\ {d}_{RSX} = {arg max}_{i = - {L}_{RSX} : {L}_{RSX}} ( {X}_{RSX} ( i ) )\end{matrix} \qquad ( 37 )$$

To normalize the maximum correlation, the following two energies are calculated using the following relations:

$$\begin{matrix}{E}_{0} = {\sum }_{n = 0}^{N - 1} {s}^{2} ( n ) \\ {E}_{1} = {\sum }_{n = 0}^{N - 1} {s}_{x}^{2} ( {d}_{RSX} + n )\end{matrix} \qquad ( 38 )$$

and X_{RSX}^{m} is divided by the square root of their product:

$${C}_{RSX} = \frac{{X}_{RSX}^{m}}{\sqrt{{E}_{0} {E}_{1}}} \qquad ( 39 )$$

The resynchronization is not applied when there is a large discrepancy between the energies of the extrapolated frame and the correctly received frame. Therefore, an energy ratio is calculated using the following relation:

$${r}_{RSX} = \frac{max ( {E}_{0} , {E}_{1} )}{min ( {E}_{0} , {E}_{1} )} . \qquad ( 40 )$$

The condition to proceed with the resynchronization is defined as:

[(last_{—}clas==VOICED) AND (C_{RSX}>0.7) AND (r_{RSX}<2.0)]

where last_clas is the classification of the signal preceding the concealed period. If this condition is satisfied the concealed signal is extended or shortened (compressed) depending on the number of samples found earlier. It should be noted that this is done for the whole concealed signal sₓ(n), i.e. for:

n=−N, . . . , 0,1, . . . , N−1.

The signal compression or expansion can be performed using different methods. For example, a “resampling” function can be used based on interpolation principle. A simple linear interpolation can be used in order to reduce complexity. However, the efficiency may be improved by employing different principles, such as quadratic or spline interpolation. If the distance between adjacent samples of the original signal is considered as “1”, the distance between adjacent samples of the resampled signal can be defined as follows:

$$Δ = \frac{N - 1 - {d}_{RSX}}{N - 1} \qquad ( 41 )$$

Since d_{RSX} is allowed to vary only in the range <−5;5>Δ may vary only in the range <0.8718;1.1282>.

The values of the resampled signal are calculated from the values of the original signal at positions given by multiples of Δ, i.e.:

p(k)=kΔ, for k=0, . . . , 2N−1 (42)

As mentioned in the foregoing description, the resampling is carried out on the whole concealed signal sₓ(n), n=−N, . . . , N−1. The resampled concealed signal s_{Rx}(n) is given by the following relation:

s_{Rx}(n)=(┌p(k)┐−p(k))·sₓ(−N+└p(k)┘)+(p(k)−└p(k)┘·sₓ(−N┌p(k)┐, for n=−N, . . . , K−1, k=n+N, (43)

where ┌p(k)┐ is the nearest higher integer value of p(k) and └p(k)┘ is the nearest lower integer value of p(k). Note that if p(k) is an integer then ┌p(k)┐=p(k)+1 and └p(k)┘=p(k). The length of the resampling operation is limited as follows:

$$K = \{ \begin{matrix}N & if {d}_{RSX} > 0 \\ N + {d}_{RSX} & if {d}_{RSX} < 0\end{matrix} \} \qquad ( 44 )$$

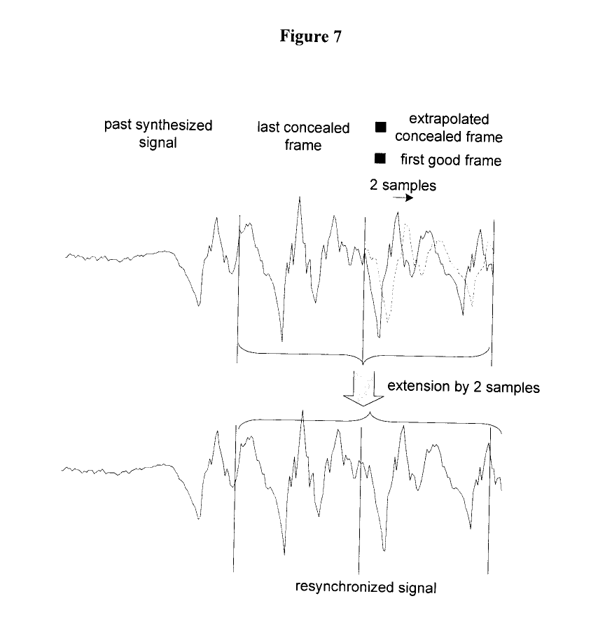

If K<N, the missing samples s_{Rx}(n), n=K, . . . , N−1, are set to zero. This is not a problem since cross-fading (OLA) which follows the resynchronization uses, as a non-limitative example, a triangular window and usually the last samples are multiplied by a factor close to zero. The principle of resynchronization is illustrated in FIG. 7 where an extension by 2 samples is performed.

After finding the resynchronized concealed signal over the past and current frames, s_{Rx}(n), n=_−N, . . . , N−1, then the concealed past frame is given by the following relation:

s_{Rx}(n), n=_{—}−N, . . . , −1 (45)

and the current frame is given by cross-fading (overlap-add) the decoded signal s(n), n=0, . . . , N−1 and the resynchronized concealed signal s_{Rx}(n). It should be noted that further processing can be applied on the resynchronized concealed signal before outputting the concealed past frame and cross-faded present frame.

The cross-fading (Overlap-Add (OLA)) an be applied for a certain number of samples L at the beginning of the current frame. The cross-faded signal is given by the following relation:

$$\begin{matrix}\overline{s} ( n ) = w ( n ) \cdot {s}_{Rx} ( n ) + ( 1 - w ( n ) ) \cdot s ( n ) , & n = 0 , … , L - 1 , \\ = s ( n ) , & n = L , … , N - 1.\end{matrix} \qquad ( 46 )$$

As a non-limitative example, a triangular window is used in the cross-fading operation, with the window given by the following relation:

$$w ( n ) = 1 - \frac{n}{L} , n = 0 , … , L - 1. \qquad ( 47 )$$

In this non-limitative example, since the frame is short (N=40), the cross-fading operation is performed over the whole frame, that is L=N.

Recovery after the Concealment

When the concealment phase is over, the recovery phase begins. The reason for doing recovery is to ensure a smooth transition between the end of the concealment and the beginning of the regular synthesis. The length of the recovery phase depends on the signal class and pitch period used during the concealment, the normalized correlation calculated in Equation (39) and energy ratio calculated in Equation (40).

The following pseudo-code is used for the decision upon the length of recovery:

```
If (clas <= UNVOICED TRANSITION)
                  L_{RCV} = N/4
Else if [(C_{RSX} > 0.7) AND (r_{RSX} < 2.6)]
    L_{RCV} = T_{OL}⁽⁰⁾ upper-limited by the value 2N
Else
    L_{RCV} = N
End.
```

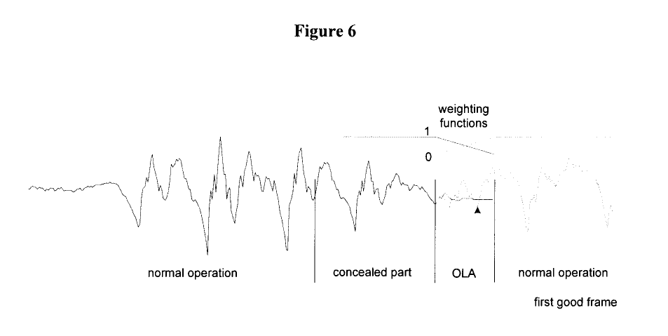

The recovery is essentially an OLA operation (recovery unit 414 in FIG. 4) carried out between the extended concealed signal and the regular synthesized signal in the length of L_{RCV}. The extension is performed on the resynchronized concealed signal, if resynchronization was done. The OLA operation has already been described in the foregoing Pre-concealment section. A graphical illustration of the OLA principle and associated weighting functions (triangular windows) is shown in FIG. 6 for the case of L_{RCV}=N.

The order and position of the FEC and recovery operations are shown in FIG. 5. In this example, the recovery phase is essentially an OLA operation and the resynchronization is conducted for the last concealed frame using the synthesized signal in the first correctly received frame after a series of frame erasures.

FEC in the Extension Layers

So far, the described FEC algorithm has been operating on the past synthesized narrowband signal (Layer 1 or Layers 1 & 2). When frames are lost, the narrowband extension part (Layer 2) is neither decoded nor concealed. It means that during the concealment phase and the recovery phase (first two (2) correctly received frames after a series of frame erasures) the Layer 2 information is not used. The first two (2) correctly received frames after FEC are omitted from the regular operation since not enough data (120 samples are necessary) is available for the LP analysis to be conducted, which is an integral part of Layer 2 synthesis.

The concealment of the wideband extension layer (Layer 3) is needed because it constitutes the HF part of the QMF synthesized wideband signal. The concealment of the HF part is not critical and it is not part of the present invention.

Although the present invention has been described in the foregoing description by way of a non-restrictive illustrative embodiment thereof, this embodiment can be modified at will within the scope of the appended claims without departing from the spirit, nature and scope of the present invention.

### REFERENCES

[1] Pulse code modulation (PCM) of voice frequencies, ITU-T Recommendation G.711, November 1988, (http://www.itu.int).
[2] Source-Controlled Variable-Rate Multimode Wideband Speech Codec (VMR-WB), Service Options 62 and 63 for Spread Spectrum Systems, 3GPP2 Technical Specification C.S0052-A v1.0, April 2005 (http://www.3gpp2.org).

What is claimed is:

1. A method for resynchronization and recovery after frame erasure concealment of an encoded sound signal, the method comprising:
in a current frame, decoding a correctly received signal after the frame erasure;
extending frame erasure concealment in the current frame, using an erasure-concealed signal from a previous frame to produce an extended erasure-concealed signal;
correlating the extended erasure-concealed signal with the decoded signal in the current frame and synchronizing the extended erasure-concealed signal with the decoded signal in response to the correlation; and
producing in the current frame a smooth transition from the synchronized extended erasure-concealed signal to the decoded signal.

2. A method for resynchronization and recovery as defined in claim 1, further comprising synchronizing the erasure-concealed signal from the previous frame with the decoded signal in response to the correlation.

3. A method for resynchronization and recovery as defined in claim 1, wherein correlating the decoded signal and the extended erasure-concealed signal comprises maximizing a cross-correlation between the extended erasure-concealed signal and the decoded signal.

4. A method for resynchronization and recovery as defined in claim 1, wherein correlating the decoded signal and the extended erasure-concealed signal comprises calculating a delay corresponding to the correlation.

5. A method for resynchronization and recovery as defined in claim 1, further comprising concatenating the erasure-concealed signal from the previous frame with the extended erasure-concealed signal in the current frame to produce a concatenated erasure-concealed signal.

6. A method for resynchronization and recovery as defined in claim 5, comprising covering a period corresponding to two frames with the concatenated erasure-concealed signal.

7. A method for resynchronization and recovery as defined in claim 2, wherein correlating the decoded signal and the extended erasure-concealed signal comprises calculating a delay corresponding to the correlation, wherein the method comprises concatenating the erasure-concealed signal from the previous frame with the extended erasure-concealed signal in the current frame to produce a concatenated erasure-concealed signal, and wherein synchronizing the extended erasure-concealed signal with the decoded signal in the current frame and synchronizing the erasure-concealed signal from the previous frame with the decoded signal in the current frame comprise resampling the concatenated erasure-concealed signal in response to the calculated delay.

8. A method for resynchronization and recovery as defined in claim 4, wherein synchronizing the extended erasure-concealed signal with the decoded signal comprises resampling the extended erasure-concealed signal in response to the calculated delay.

9. A method for resynchronization and recovery as defined in claim 7, wherein resampling the concatenated erasure-concealed signal in response to the calculated delay comprises compressing or expanding the concatenated erasure-concealed signal depending on whether the calculated delay is positive or negative.

10. A method for resynchronization and recovery as defined in claim 8, wherein resampling the extended erasure-concealed signal in response to the calculated delay comprises compressing or expanding the extended erasure-concealed signal depending on whether the calculated delay is positive or negative.

11. A method for resynchronization and recovery as defined in claim 9, wherein compressing the concatenated erasure-concealed signal comprises removing a number of samples corresponding to a value of the calculated delay.

12. A method for resynchronization and recovery as defined in claim 9, wherein expanding the concatenated erasure-concealed signal comprises inserting a number of samples corresponding to a value of the calculated delay.

13. A method for resynchronization and recovery as defined in claim 1, wherein synchronizing the extended erasure-concealed signal with the decoded signal in response to the correlation comprises aligning a phase of the extended erasure-concealed signal with the decoded signal.

14. A method for resynchronization and recovery as defined in claim 1, comprising extracting the erasure-concealed signal from the previous frame to produce a synthesized signal in the previous frame.

15. A method for resynchronization and recovery as defined in claim 1, wherein producing a smooth transition comprises performing an crossfading operation on the extended erasure-concealed signal and the decoded signal in the current frame.

16. A method for resynchronization and recovery as defined in claim 5, wherein producing a smooth transition comprises performing an Overlap-Add operation on overlapping parts of the concatenated erasure-concealed signal and the decoded signal in the current frame.

17. A method for resynchronization and recovery as defined in claim 16, wherein performing the Overlap-Add operation comprises producing a synthesized signal in the current frame.

18. A method for resynchronization and recovery as defined in claim 16, wherein performing the Overlap-Add operation comprises using a triangular window.

19. A method for resynchronization and recovery as defined in claim 16, wherein performing the Overlap-Add operation comprises calculating a length of the Overlap-Add operation.

20. A method for resynchronization and recovery as defined in claim 1, further comprising determining a signal classification of the encoded sound signal.

21. A method for resynchronization and recovery as defined in claim 20, wherein determining the signal classification of the encoded sound signal comprises classifying the encoded sound signal into a group consisting of unvoiced, unvoiced transition, voiced transition, voiced and onset signals.

22. A method for resynchronization and recovery as defined in claim 20, wherein determining the signal classification comprises calculating parameters selected from the group consisting of a pitch coherence, a zero-crossing rate, a correlation, a spectral tilt and an energy difference related to the encoded sound signal in order to determine the signal classification of the encoded sound signal.

23. A method for resynchronization and recovery as defined in claim 1, further comprising performing synchronization of the extended erasure-concealed signal with the decoded signal only for voiced signals.

24. A method for resynchronization and recovery as defined in claim 22, wherein calculating the energy difference comprises calculating a ratio of energies between the extended erasure-concealed signal and the decoded signal in the current frame.

25. A device for resynchronization and recovery after frame erasure concealment of an encoded sound signal, the device comprising:
a decoder for decoding, in a current frame, a correctly received signal after the frame erasure;
a concealed signal extender for producing an extended erasure-concealed signal in the current frame using an erasure-concealed signal from a previous frame;
a correlator of the extended erasure-concealed signal with the decoded signal in the current frame and a synchronizer of the extended erasure-concealed signal with the decoded signal in response to the correlation; and
a recovery unit supplied with the synchronized extended erasure-concealed signal with the decoded signal, the recovery unit being so configured as to produce in the current frame a smooth transition from the synchronized extended erasure-concealed signal to the decoded signal.

26. A device for resynchronization and recovery as defined in claim 25, wherein the synchronizer also synchronizes the erasure-concealed signal from the previous frame with the decoded signal in response to the correlation.

27. A device for resynchronization and recovery as defined in claim 25, wherein the correlator comprises maximizing a cross-correlation between the extended erasure-concealed signal and the decoded signal.

28. A device for resynchronization and recovery as defined in claim 25, wherein the correlator calculates a delay corresponding to the correlation.

29. A device for resynchronization and recovery as defined in claim 25, comprising means for concatenating the erasure-concealed signal from the previous frame with the extended erasure-concealed signal in the current frame to produce a concatenated erasure-concealed signal.

30. A device for resynchronization and recovery as defined in claim 26, wherein the correlator calculates a delay corresponding to the correlation, wherein the device comprises means for concatenating the erasure-concealed signal from the previous frame with the extended erasure-concealed signal in the current frame to produce a concatenated erasure-concealed signal, and wherein the synchronizer comprises a resampler of the concatenated erasure-concealed signal in response to the calculated delay.

31. A device for resynchronization and recovery as defined in claim 28, wherein the synchronizer comprises a resampler of the extended erasure-concealed signal in response to the calculated delay.

32. A device for resynchronization and recovery as defined in claim 30, wherein the resampler of the concatenated erasure-concealed signal in response to the calculated delay comprises a compressor or expander of the concatenated erasure-concealed signal depending on whether the calculated delay is positive or negative.

33. A device for resynchronization and recovery as defined in claim 31, wherein the resampler of the extended erasure-concealed signal in response to the calculated delay comprises a compressor or expander of the extended erasure-concealed signal depending on whether the calculated delay is positive or negative.

34. A device for resynchronization and recovery as defined in claim 32, wherein the compressor of the concatenated erasure-concealed signal removes a number of samples corresponding to a value of the calculated delay.

35. A device for resynchronization and recovery as defined in claim 32, wherein the expander of the concatenated erasure-concealed signal inserts a number of samples corresponding to a value of the calculated delay.

36. A device for resynchronization and recovery as defined in claim 25, wherein the synchronizer of the extended erasure-concealed signal with the decoded signal in response to the correlation aligns a phase of the extended erasure-concealed signal with the decoded signal.

37. A device for resynchronization and recovery as defined in claim 25, comprising means for extracting the erasure-concealed signal from the previous frame to produce a synthesized signal in the previous frame.

38. A device for resynchronization and recovery as defined in claim 25, wherein the recovery unit performs an Overlap-Add operation on the extended erasure-concealed signal and the decoded signal in the current frame.

39. A device for resynchronization and recovery as defined in claim 29, wherein the recovery unit performs an Overlap-Add operation on overlapping parts of the concatenated erasure-concealed signal and the decoded signal in the current frame to produce a synthesized signal in the current frame.

40. A device for resynchronization and recovery as defined in claim 38, wherein recovery unit uses a triangular window to perform the Overlap-Add operation.

41. A device for resynchronization and recovery as defined in claim 25, further comprising determining a signal classification of the encoded sound signal.
